(19) United States
(12) Patent Application Publication
(10) Pub. No.: US 2016/0358857 A1
(43) Pub. Date: Dec. 8, 2016

(54) SEMICONDUCTOR DEVICE AND METHOD OF MANUFACTURING THE SAME

(71) Applicant: Kabushiki Kaisha Toshiba, Minato-ku (JP)

(72) Inventors: Miyuki KOUDA, Yokkaichi (JP); Koichi MATSUNO, Mie (JP)

(73) Assignee: Kabushiki Kaisha Toshiba, Minato-ku (JP)

(21) Appl. No.: 14/848,793

(22) Filed: Sep. 9, 2015

Related U.S. Application Data
(60) Provisional application No. 62/172,411, filed on Jun. 8, 2015.

(51) Int. Cl. H01L 23/535; H01L 21/768

(52) U.S. Cl. CPC H01L 23/535; H01L 21/76805; H01L 21/7682; H01L 21/76829; H01L 21/76843; H01L 21/76865; H01L 21/76895

(57) ABSTRACT

A semiconductor device is described below that includes a semiconductor substrate, a conductive film mounted on the semiconductor substrate, and an interlayer dielectric film covering the conductive film and the semiconductor substrate. A first contact extends from a surface of the interlayer dielectric film to the semiconductor substrate, and a second contact extends from a surface of the interlayer dielectric film to the conductive film. An amorphous silicon film is disposed between the first or second contact and the interlayer dielectric film.

### CROSS REFERENCE TO RELATED APPLICATIONS

This application is based on and claims the benefit of priority from prior US prior provisional Patent Application No. 62/172,411, filed on Jun. 8, 2015, the entire contents of which are incorporated herein by reference.

### BACKGROUND

Field

The embodiments described herein relate to a semiconductor device and a method of manufacturing the same.

Description of the Related Art

In the recent semiconductor devices such as a non-volatile semiconductor memory device, wiring lines become finer. In forming a large number of contact holes connected to such finer wiring lines, it becomes hard to form the contacts correctly while preventing the penetration of the contact holes.

### BRIEF DESCRIPTION OF THE DRAWINGS

FIG. 1 is a block diagram of a non-volatile semiconductor memory device according to a first embodiment;

FIG. 2 is a circuit diagram showing a portion of the configuration of the non-volatile semiconductor memory device according to the first embodiment;

FIG. 3 is a schematic planar layout showing a portion of the configuration of the non-volatile semiconductor memory device according to the first embodiment;

FIG. 4 is a schematic cross-sectional view showing a portion of the configuration of the non-volatile semiconductor memory device according to the first embodiment;

FIG. 5 is a schematic cross-sectional view showing a portion of the configuration of the non-volatile semiconductor memory device according to the first embodiment;

FIG. 6 is a cross-sectional view showing a process of manufacturing the non-volatile semiconductor memory device according to the first embodiment;

FIG. 7 is a cross-sectional view showing the process of manufacturing the non-volatile semiconductor memory device according to the first embodiment;

FIG. 8 is a cross-sectional view showing the process of manufacturing the non-volatile semiconductor memory device according to the first embodiment;

FIG. 9 is a cross-sectional view showing the process of manufacturing the non-volatile semiconductor memory device according to the first embodiment;

FIG. 10 is a cross-sectional view showing the process of manufacturing the non-volatile semiconductor memory device according to the first embodiment;

FIG. 11 is a cross-sectional view showing the process of manufacturing the non-volatile semiconductor memory device according to the first embodiment;

FIG. 12 is a cross-sectional view showing the process of manufacturing the non-volatile semiconductor memory device according to the first embodiment;

FIG. 13 is a cross-sectional view showing the process of manufacturing the non-volatile semiconductor memory device according to the first embodiment;

FIG. 14 is a cross-sectional view showing the process of manufacturing the non-volatile semiconductor memory device according to the first embodiment;

FIG. 15 is a cross-sectional view showing the process of manufacturing the non-volatile semiconductor memory device according to the first embodiment;

FIG. 16 is a cross-sectional view showing the process of manufacturing the non-volatile semiconductor memory device according to the first embodiment;

FIG. 17 is a cross-sectional view showing the process of manufacturing the non-volatile semiconductor memory device according to the first embodiment;

FIG. 18 is a cross-sectional view showing the process of manufacturing the non-volatile semiconductor memory device according to the first embodiment;

FIG. 19 is a cross-sectional view showing the process of manufacturing the non-volatile semiconductor memory device according to the first embodiment;

FIG. 20 is a schematic cross-sectional view of a portion of the configuration of a non-volatile semiconductor memory device according to a second embodiment;

FIG. 21 is a cross-sectional view showing a process of manufacturing the non-volatile semiconductor memory device according to the second embodiment;

FIG. 22 is a cross-sectional view showing the process of manufacturing the non-volatile semiconductor memory device according to the second embodiment;

FIG. 23 is a cross-sectional view showing the process of manufacturing the non-volatile semiconductor memory device according to the second embodiment; and

FIG. 24 is a cross-sectional view showing the process of manufacturing the non-volatile semiconductor memory device according to the second embodiment.

### DETAILED DESCRIPTION

A semiconductor device is described below that includes a semiconductor substrate, a conductive film mounted on the semiconductor substrate, and an interlayer dielectric film covering the conductive film and the semiconductor substrate. A first contact extends from a surface of the interlayer dielectric film to the semiconductor substrate, and a second contact extends from a surface of the interlayer dielectric film to the conductive film. An amorphous silicon film is disposed between the first or second contact and the interlayer dielectric film.

Referring to the drawings, embodiments of a semiconductor device and a method of manufacturing the same will be described below. Although a non-volatile semiconductor memory device will be described below as an example of the semiconductor device, the present invention may generally apply to a semiconductor device that includes a semiconductor substrate, a conductive film formed on its surface, and a contact connected to the substrate and the film.

### First Embodiment

### Entire Configuration

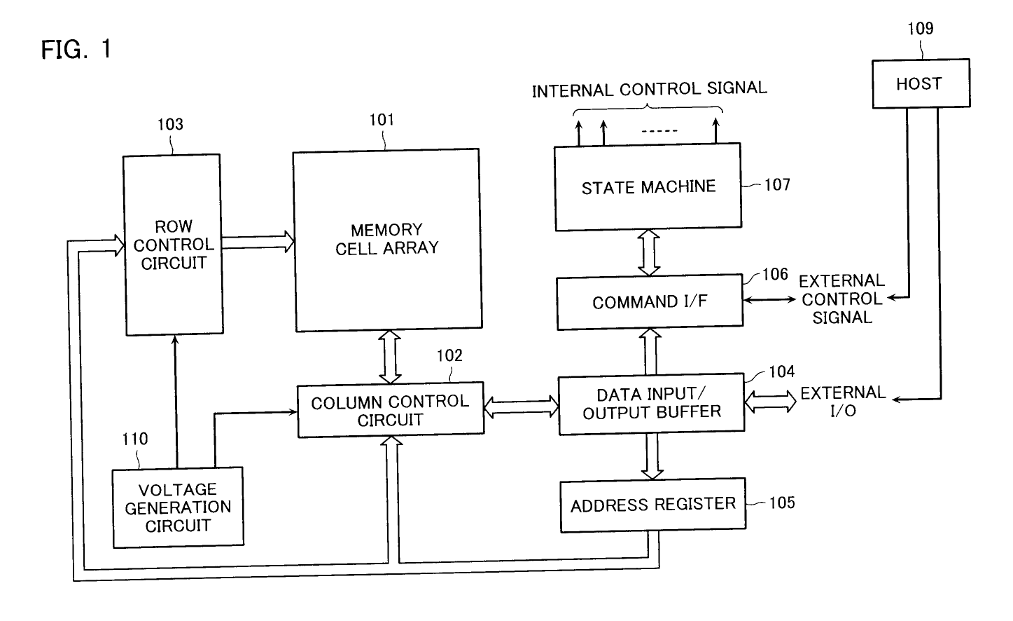

FIG. 1 is a block diagram of a non-volatile semiconductor memory device according to a first embodiment. The non-volatile semiconductor memory device includes a memory cell array 101. The memory cell array 101 includes a plurality of memory cells MC disposed in a generally matrix as well as bit lines BL and word lines WL connected to the memory cells MC. The bit lines BL and the word lines WL are perpendicular to each other. The memory cell array 101 has therearound a column control circuit 102 and a row control circuit 103. The column control circuit 102 controls the bit lines BL, erases data in the memory cells, writes data in the memory cells, and reads data from the memory cells. The row control circuit 103 selects a word line WL, and applies a voltage for erasing data in the memory cells, writing data in the memory cells, and reading data from the memory cells.

A data input/output buffer 104 is connected to an external host 109 via an I/O line. The data input/output buffer 104 receives write data, receives erase command, outputs read data, and receives address data and command data from the external host 109. The data input/output buffer 104 sends the received write data to the column control circuit 102, receives data read from the column control circuit 102, and outputs it externally. The address externally provided to the data input/output buffer 104 is sent via an address register 105 to the column control circuit 102 and the row control circuit 103.

In addition, the command provided from the host 109 to the data input/output buffer 104 is sent to a command interface 106. The command interface 106 receives an external control signal from the host 109 and determines whether data input to the data input/output buffer 104 is write data, a command, or an address. If the data is a command, the command interface 106 transfers it to a state machine 107 as a received command signal.

The state machine 107 manages the entire non-volatile memory. The state machine 107 receives a command from the host 109 via the command interface 106 to manage data receiving, reading, writing, erasing, input/output or the like.

In addition, the external host 109 may receive status information managed by the state machine 107 to determine the operation result. In addition, the status information is also used in controlling write and erase.

In addition, the state machine 107 controls a voltage generation circuit 110. This control may allow the voltage generation circuit 110 to output any voltage and any timing pulse.

Here, the formed pulse may be transferred to any wiring line selected by the column control circuit 102 and the row control circuit 103. The column control circuit 102, the row control circuit 103, the state machine 107, and the voltage generation circuit 110 or the like form the control circuit in this embodiment.

### [Memory Cell Array 101]

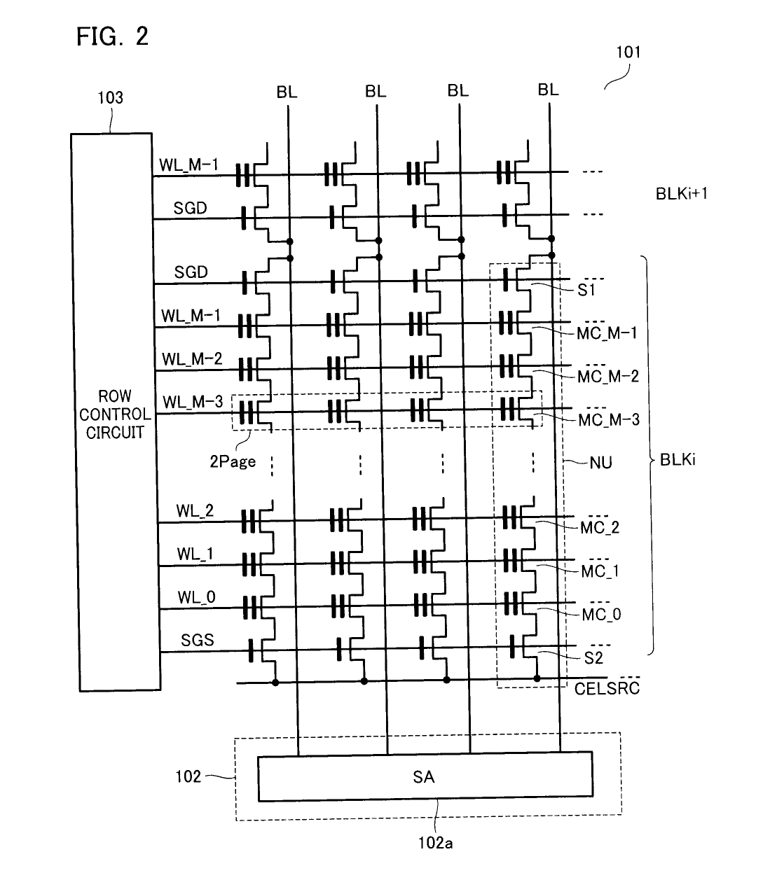

FIG. 2 is a circuit diagram showing the configuration of the memory cell array 101. As shown in FIG. 2, the memory cell array 1 includes an array of a plurality of NAND cell units NU. Each NAND cell unit NU includes a NAND string and select gate transistors S1 and S2 connected to the opposite ends of the NAND string. The NAND string includes electrically rewritable M non-volatile memory cells MC_0 to MC_M−1 connected in series. The non-volatile memory cells MC_0 to MC_M−1 share sources and drains.

The NAND cell unit NU has a first end (on the select gate transistor S1 side) connected to a bit line BL and a second end (on the select gate transistor S2 side) connected to a common source-line CELSRC. The select gate transistors S1 and S2 have gate electrodes connected to respective select gate lines SGD and SGS. In addition, the memory cells MC_0 to MC_M−1 have control gate electrodes connected to respective word lines WL_0 to WL_M−1. The bit lines BL are connected to a sense amplifier 102a of the column control circuit 102. The word lines WL_0 to WL_M−1 and the select gate lines SGD and SGS are connected to the row control circuit 103.

For 2-bit/cell in which one memory cell MC stores 2-bit data, data stored in a plurality of memory cells MC connected to one word line WL forms data of 2 pages (an upper page UPPER and a lower page LOWER).

A plurality of NAND cell units NU sharing a word line WL form one block BLK. One block BLK forms one unit for a data erase operation. In one memory cell array 1, one block BLK includes M word lines WL and one block includes M×2 pages for 2-bit/cell.

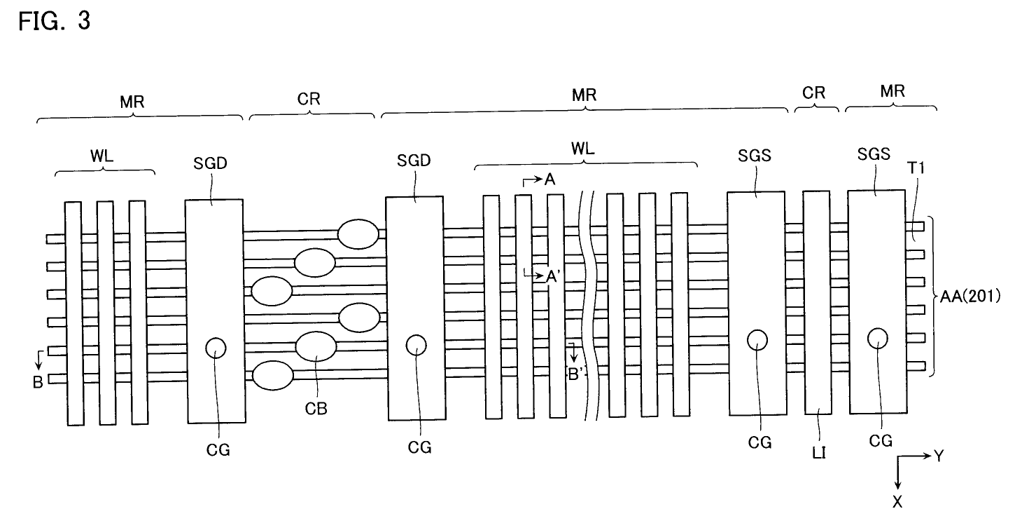

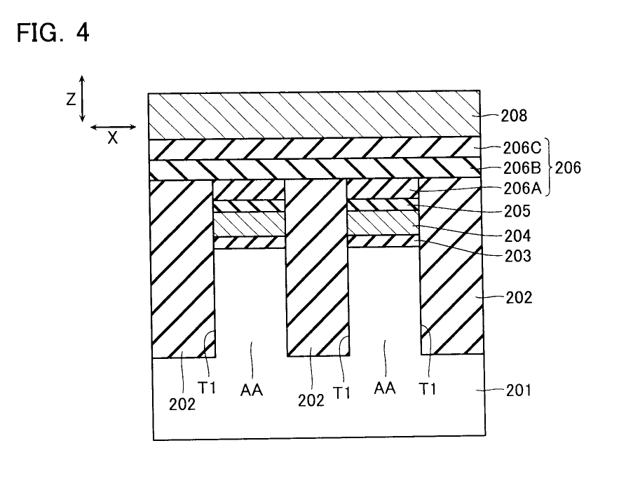

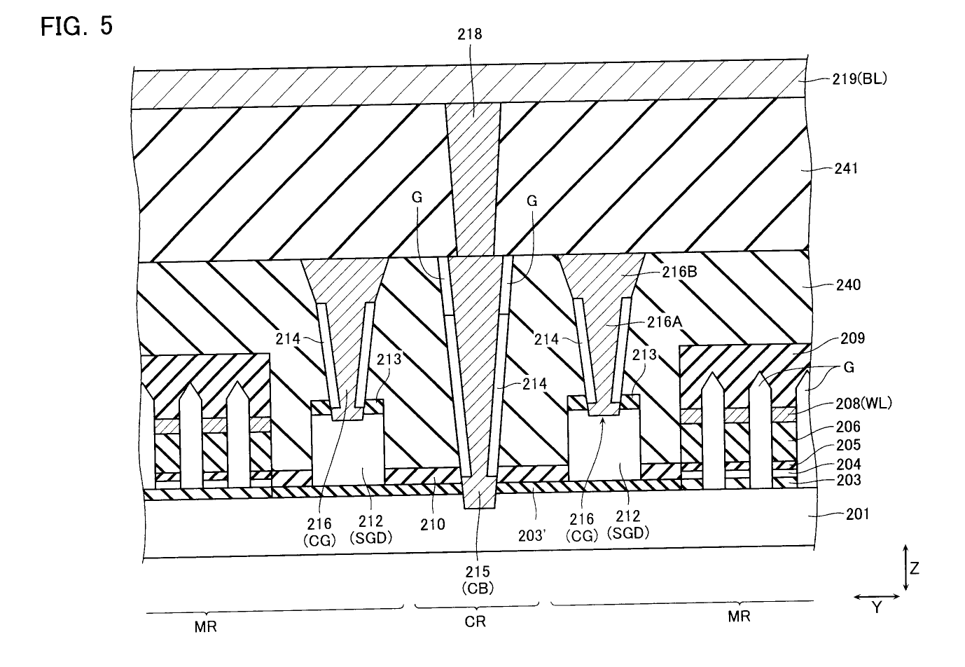

Next, with reference to FIGS. 3 to 5, the detailed structure of the memory cell array 101 will be described. FIG. 3 is a plan view showing a specific structure of the memory cell array 101. FIG. 4 is a cross-sectional view along the A-A in FIG. 3. FIG. 5 is a cross-sectional view along the B-B in FIG. 3.

As shown in FIG. 3, the memory cell array 101 includes active areas AA. The active areas AA are disposed, with the longitudinal direction in the Y-direction in FIG. 3, in the X-direction at a predetermined interval. The active areas AA are regions of a semiconductor substrate 201 that remain after the substrate 201 is divided by trenches T1 extending in the Y-direction. Each trench T1 is embedded with an insulating separation film. The insulating separation films electrically isolate the active areas AA arranged in the X-direction from each other.

The active areas AA have thereon memory regions MR where the memory cells MCs and the select gate transistors S1 and S2 are formed and contact regions CR where contacts CB and LI are formed.

Each memory region MR includes the word lines WL and the select gate lines SGD and SGS extending in the X-direction as the longitudinal direction. The X-direction intersects the Y-direction that is the longitudinal direction of the active areas AA. The memory cells MC are provided at the intersections between the word lines WL and the active areas AA. The select gate transistors S1 and S2 are provided at the intersections between the select gate lines SGD and SGS and the active area AA. Note that the select gate lines SGD and SGS have a contact CG connected to their surfaces, as described below. Each contact CG extends upward from the surface of the select gate line SGD or SGS to electrically connect an external driver circuit and the select gate transistor S1 or S2.

In addition, in the contact regions CR, the contacts CB connect the sources or drains of the select gate transistors S1 and the bit lines BL. Each contact CB is provided in a columnar shape having a longitudinal direction in the direction perpendicular to the plane (Z-direction). The contacts CB are connected to the respective active areas AA arranged in the X-direction.

In addition, in the contact regions CR, the contacts LI connect the select gate transistors S2 and the source-lines CELSRC. Each contact LI is formed with a longitudinal direction in the direction perpendicular to the plane. Each contact LI has a plate shape that is commonly connected to the active areas AA arranged in the X-direction.

Next, with reference to FIG. 4, the cross-sectional shape along the A-A′ in FIG. 3, i.e., the cross-sectional shape along the longitudinal direction of the word lines WL of a memory cell MC will be described.

The memory cell MCs are formed on the semiconductor substrate 201 as shown in FIG. 4. As described above, the semiconductor substrate 201 has, on its surface, element isolation insulating films 202. The isolation insulating films 202 extend in the Y-direction as the longitudinal direction and are formed in the X-direction at a predetermined interval. The element isolation insulating films 202 are formed of, for example, silicon oxide (SiO₂). The regions of the semiconductor substrate 201 sandwiched between the element isolation insulating films 202 provides the active areas AA where the memory cells MC and select transistors S1 and S2 are formed. In other words, the surface of the semiconductor substrate 201 is electrically isolated by the element isolation insulating films 202 into the active areas AA. The active areas AA extend, like the element isolation insulating films 202, in the Y-direction as the longitudinal direction and are formed in the X-direction at a predetermined interval.

Each memory cell MC includes, on the surface of an active area AA, a gate-insulating film 203 (a tunnel insulating film) and a floating gate electrode 204 disposed on the gate-insulating film 203. The gate-insulating film 203 may have a film thickness set to, for example, about 6 nm. In addition, the floating gate electrode 204 may have a film thickness set to, for example, about 10 to 25 nm.

Further, each memory cell MC includes a charge accumulation film 205 disposed on the floating gate electrode 204. The charge accumulation film 205 has a function of accumulating a charge injected in the floating gate electrode 204 via the gate-insulating film 203 by the write operation. The charge accumulation film 205 is formed of, for example, silicon nitride (SiN). The charge accumulation film 205 may have a film thickness set to, for example, about 2 nm. The existence of the charge accumulation film 205 may reduce the aspect ratio of the floating gate electrode 204.

On the charge accumulation film 205, a block insulating film 206 is formed. The block insulating film 206 includes, by way of example, a first insulating film 206A formed of hafnium oxide (HfOx), a second insulating film 206B formed of silicon oxide (SiO2), and a third insulating film 206C formed of hafnium oxide (HfOx).

On the block insulating film 206, a conductive film 208 as a word line WL is deposited via a barrier metal (not shown). The first insulating film 206A, the second insulating film 206B, and the third insulating film 206C may each have a film thickness set to, by way of example, about 5 nm. FIG. 4 shows an example where after the CMP method, the first insulating film 206A has a top surface generally flush with the top surface of the element isolation insulating film 202 in the Z-direction height and is provided only between the element isolation insulating films 202. Then, the second and third insulating films 206B and 206C are formed on the flattened top surfaces of the first insulating film 206A and the element isolation insulating film 202. The films 206B and 206C are formed in a stripe pattern that has a longitudinal direction in the X-axis like the word lines WL. In addition, the conductive film 208 is formed of a metal such as tungsten (W).

Note that although the block insulating film 206 has a three-layer structure in the shown example, it is not limited thereto. The block insulating film 206 may also have a single layer structure formed of a single material. In addition, between the charge accumulation layer 205 and the block insulating film 206, and between the block insulating film 206 and the barrier metal (not shown), an interface layer may exist.

FIG. 4 shows a memory cell having a so-called flat cell structure in which the element isolation insulating film 202 has a top surface higher than the surface of the floating gate electrode 204. Note, however, that this is only by way of example, and the technology of this embodiment may also apply to a structure (also called a rocket cell structure) in which the element isolation insulating film 202 has a top surface lower than the surface of the floating gate electrode 204. In addition, the same technology may also apply to a memory cell array including memory cells arranged three-dimensionally.

Next, with reference to FIG. 5, the cross-sectional shape along the B-B′ in FIG. 3, i.e., the cross-sectional shape along the longitudinal direction of the bit lines BL will be described.

As shown in FIG. 5, in each memory region MR, the memory cells MC forming the above NAND string are connected in series along the longitudinal direction of the bit lines BL. The stack of the gate-insulating film 203, the floating gate electrode 204, the charge accumulation film 205, the block insulating film 206, and the word line 208 as described above is divided into a plurality of stacks in the Y-direction. Each stack provides the gate electrode of one memory cell MC. The gate electrode structures (stacks) of two adjacent memory cells are isolated by an air gap G.

In addition, the upper portions of the gate electrode structures of the memory cells MC are covered by an insulating layer 209. Furthermore, the upper portion of the insulating layer 209 is covered by an interlayer dielectric film 240. The insulating layer 209 is formed not to be embedded in the air gap G. The insulating layer 209 is thus formed of an insulating film having a poor embedding property such as, for example, silane (SiH₄). In addition, the interlayer dielectric film 240 is configured by, for example, a material such as polysilazane. In addition, the upper portion of the interlayer dielectric film 240 is further deposited with an interlayer dielectric film 241 including a dTEOS film or the like. On the upper portion of the interlayer dielectric film 241, a conductive layer 219 is formed that provides a bit line BL, for example. The conductive layer 219 is formed of, for example, a metal film such as tungsten (W). Note that each layer's material may be changed as appropriate.

In addition, on the surface of the active area AA that is adjacent to the memory cells MC, a conductive film 212 is formed via a gate-insulating film 203′. The conductive film 212 is formed of a material such as, for example, polysilicon. The film 212 functions as the gate electrode (the select gate line SGD) of the select gate transistor S1. On the surface of the conductive film 212, a silicide film may be formed. In addition, on the surface of the conductive film 212, a cap layer 213 is formed. The cap layer 213 is formed of, for example, a material such as a silicon nitride film. Note that although FIG. 5 only shows the cross-sectional structure of the select gate transistor S1 and not of the select gate transistor S2, the select gate transistor S2 has the same gate structure as the select gate transistor S1. The conductive film 212 and the cap layer 213 are also covered by the interlayer dielectric films 240 and 241. Note that although in the shown example, the gate electrodes of the select gate transistors S1 and S2 include the conductive film 212, the structures of the select gate transistors S1 and S2 are not limited thereto and may be, for example, the same as those of the memory cells MC.

As the wiring lines for electrically connecting the select gate transistor S1 externally, the contacts CB and CG are formed extending from the surface of the interlayer dielectric film 240 to the semiconductor substrate 201 and the conductive film 212 (the select gate line SGD), respectively. Meanwhile, the contact CB is formed extending from the surface of the interlayer dielectric film 240 through the gate-insulating film 203 and the stopper film 210, which are formed on the semiconductor substrate 201, and connected to the source or drain of the select gate transistor S1. The stopper film, 210 is formed of, for example, a material such as a silicon nitride film.

Meanwhile, the contact CG is formed extending from the surface of the interlayer dielectric film 240 through the cap film 213 formed on the surface of the conductive film 212. The contact CB has an upper end connected to the upper-layer wiring line 219 via a wiring line 218. The upper-layer wiring line 219 is formed of, for example, a metal material such as tungsten and functions as, for example, a bit line BL. The contact CG is also connected to an external circuit via a not-shown contact and a not-shown upper-layer wiring line. Note that although not shown, the contact LI is formed, like the contact CB, extending from the surface of the interlayer dielectric film 240 to the semiconductor substrate 201.

The contacts CB and CG are formed of respective metal films 215 and 216. The metal films 215 and 216 include, for example, a metal such as tungsten. The metal film 216 included in the contact CG includes a first metal film 216A and a second metal film 216B. The first metal film 216A has a lower end in contact with the conductive film 212. The second metal film 216B is positioned on the upper end side of the first metal film 216A and is wider than the first metal film 216A. The second metal film 216B is connected, on its upper layer side, to a not-shown contact and a not-shown upper-layer wiring line.

In addition, between the metal films 215 and 216 and the interlayer dielectric film 240, i.e., on the side wall of the trench where the metal films 215 and 216 are embedded, an amorphous silicon film 214 is formed along the side wall of the trench.

Note, however, that, in the contact CB, the amorphous silicon film 214 is not formed near the surface of the interlayer dielectric film 240 and has an upper end lower than the surface of the interlayer dielectric film 240. Specifically, the amorphous silicon layer 214 is formed to have an upper end lower than the second metal film 216B and the amorphous silicon film 214 is not formed on the side surface of the second metal film 216B.

Then, between the upper end of the amorphous silicon film 214 and the surface of the interlayer dielectric film 240, the air gap G is formed. The air gap G formed may enhance the breakdown voltage characteristics between the adjacent contacts. Because the amorphous silicon film has poor breakdown voltage characteristics compared to the silicon oxide film, an amorphous silicon film remaining near the surface of the interlayer dielectric film 240 may degrade the breakdown voltage characteristics compared to an silicon oxide film formed near the surface. Therefore, this embodiment eliminates the amorphous silicon film in the relevant portion to form the air gap G, thus improving the breakdown voltage characteristics.

Note, however, that whether the air gap G is to be formed depends on the necessary breakdown voltage. To the extent that the necessary breakdown voltage is sufficiently held, a configuration may be used in which the air gap G is not formed and the amorphous silicon film 214 remains near the surface of the interlayer dielectric film 240.

### [Manufacturing Method]

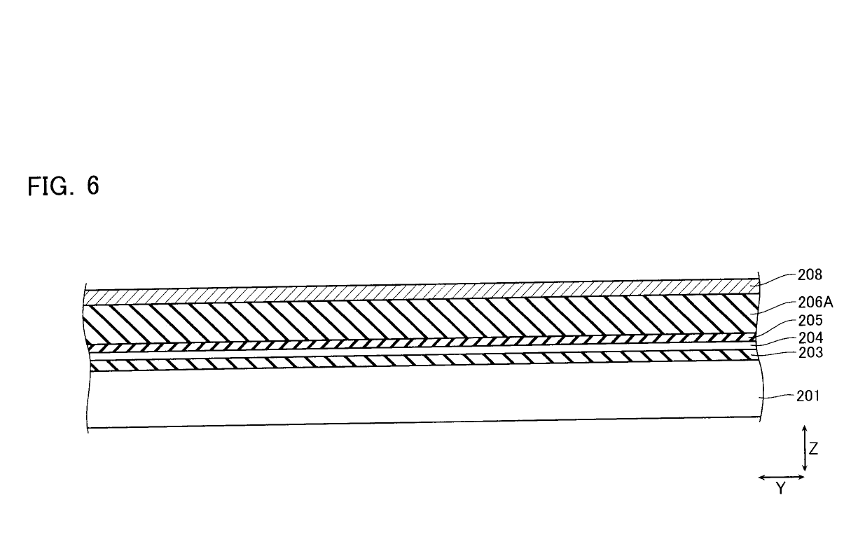

Next, with reference to FIGS. 6 to 14, a method of manufacturing a non-volatile semiconductor memory device according to this embodiment will be described. FIGS. 6 to 14 are cross-sectional views showing the manufacturing process of the non-volatile semiconductor memory device.

First, as shown in FIG. 6, on the semiconductor substrate 201 (the active area AA), the following materials are stacked sequentially: the gate-insulating film 203, the floating gate electrode 204, the charge accumulation film 205, the insulating film 206 (206A to 206C), and the conductive film 208.

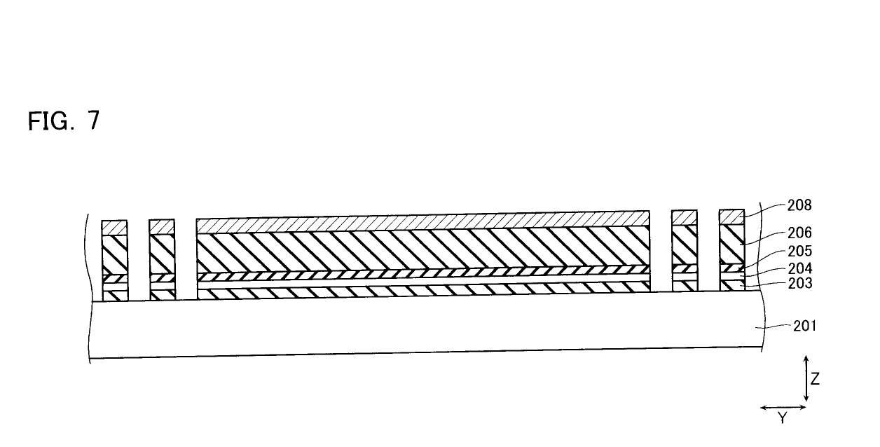

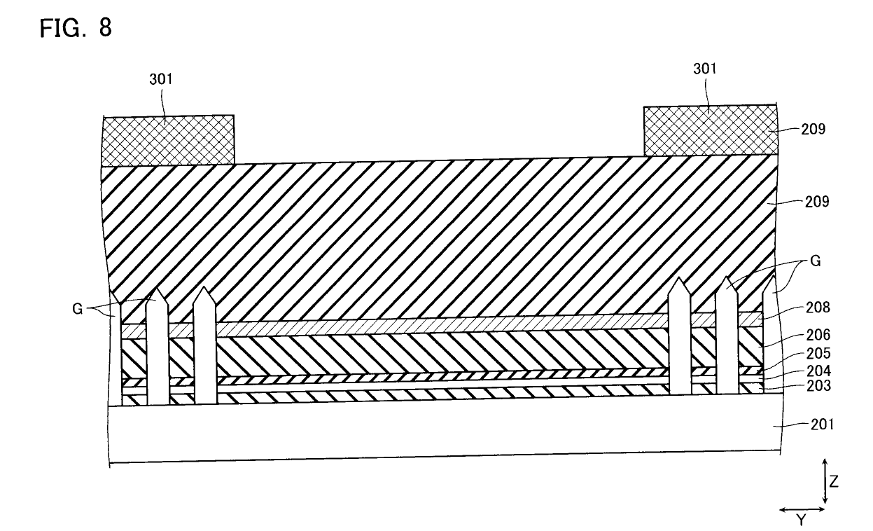

Then, as shown in FIG. 7, the following materials in the memory region MR are divided in the Y-direction to form the gate electrode structures of the memory cells MC: the gate-insulating film 203, the floating gate electrode 204, the charge accumulation film 205, the insulating film 206, and the conductive film 208. Then, as shown in FIG. 8, the insulating layer 209 is formed on the entire top surface of the substrate 201 including the top surfaces of the gate electrode structures. The insulating layer 209 is formed of a material having poor embeddability such as, for example, plasma silane (P-SiH₄). Thus, the above air gap G is formed between the memory cells MC adjacent in the first direction.

Next, as shown in FIG. 8, on the top surface of the insulating layer 209, a resist 301 is formed. The resist 301 covers only the portion of the memory cell region MR where the memory cells MC are formed. The resist 301 does not cover the portion where the select gate transistors S1 and S2 are formed or the contact regions CR.

Next, as shown in FIG. 9, the resist 301 is used as a mask to remove the gate-insulating film 203, the floating gate electrode 204, the charge accumulation film 205, the block insulating film 206, the conductive film 208B, and the insulating film 209. Thus, in the region where the select gate transistors S1 and S2 are formed and the contact regions CR, the substrate 201 is exposed.

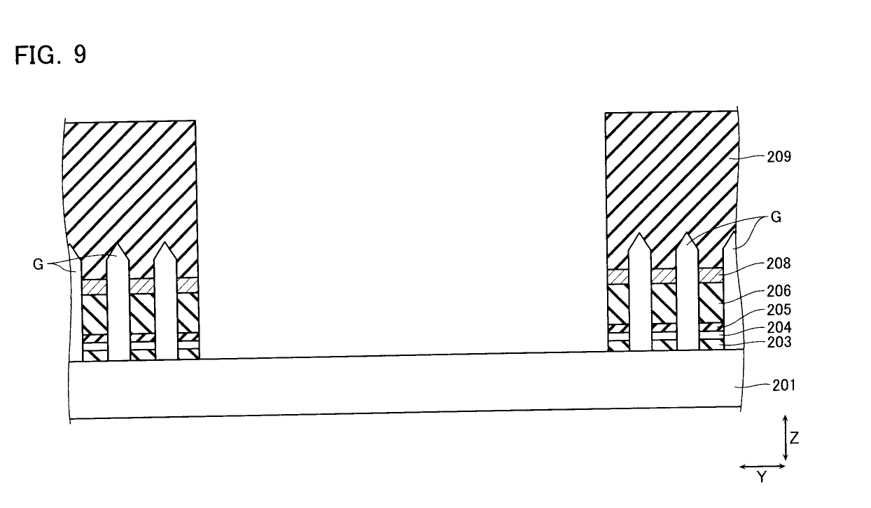

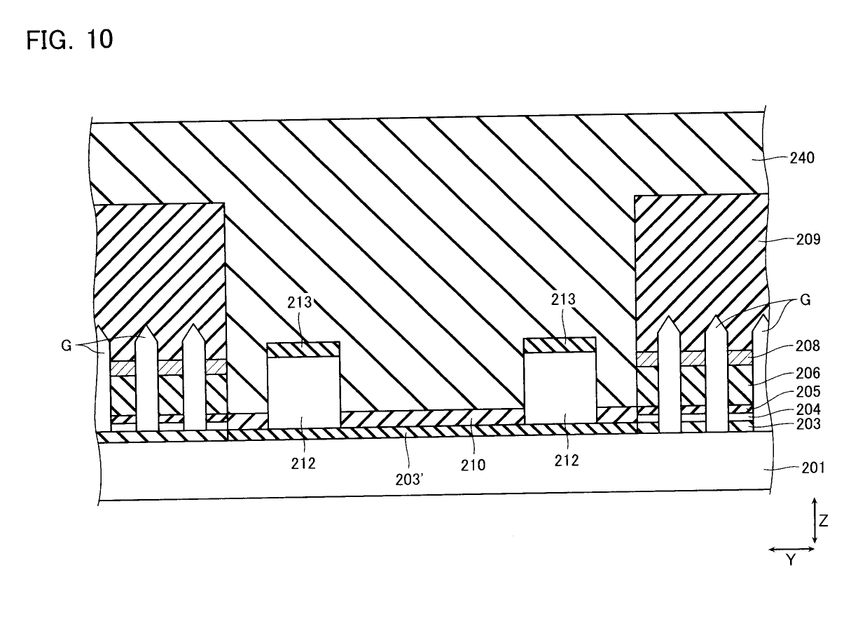

Then, although the details are omitted, the well-known techniques such as the CVD method, the photolithography, and the etching are used to form the gate electrode structures of the select gate transistors S1 and S2, as shown in FIG. 10.

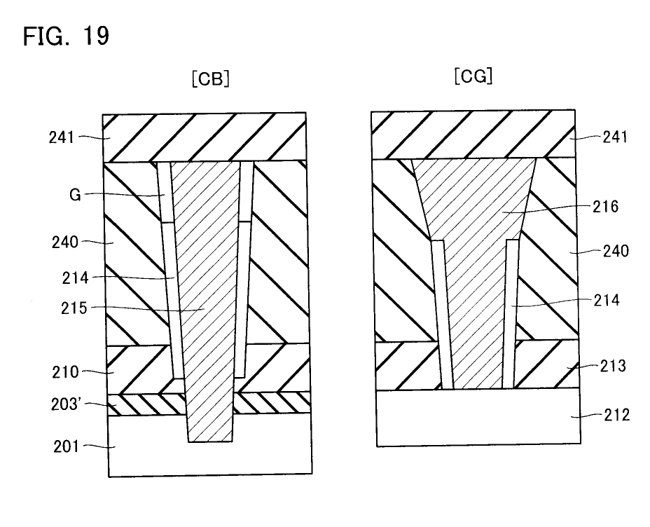

Next, with reference to FIGS. 11 to 19, a process of manufacturing the contacts CB and CG will be described. FIG. 11 to 19 are schematic cross-sectional views enlarging only the portions of the contacts CB and CG. FIGS. 11 to 19 show the cross-sectional view of the contact CB portion on the left side and the cross-sectional view of the contact CG portion on the right side.

First, as shown in FIG. 11, the photolithography and the etching are used to concurrently form, from the surface of the interlayer dielectric film 240, the trench Tb extending to the stopper film 210 and the trench Tg extending to the conductive film 212. Because both of the stopper film 210 and the cap film 213 may be formed of a silicon nitride film, the etching rate is reduced at the positions of the stopper film 210 and the cap film 213. Note, however, that because the cap film 213 is higher than the stopper film 210, the trench Tg passes through the cap film 213, while the processing of the trench Tb is stopped when only the surface of the stopper film 210 is removed.

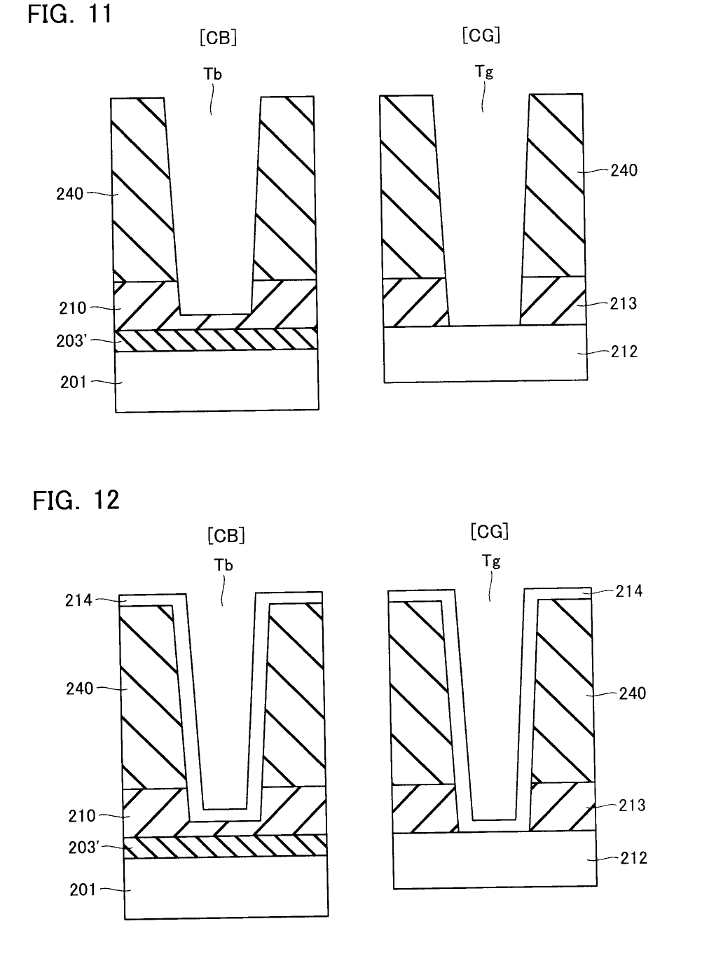

Next, as shown in FIG. 12, the entire surface of the interlayer dielectric film 240 including the inner walls of the trenches Tb and Tg is deposited with the amorphous silicon film 214 having a film thickness of about 7 to 11 nm, preferably about 9 nm, using the CVD method or the like.

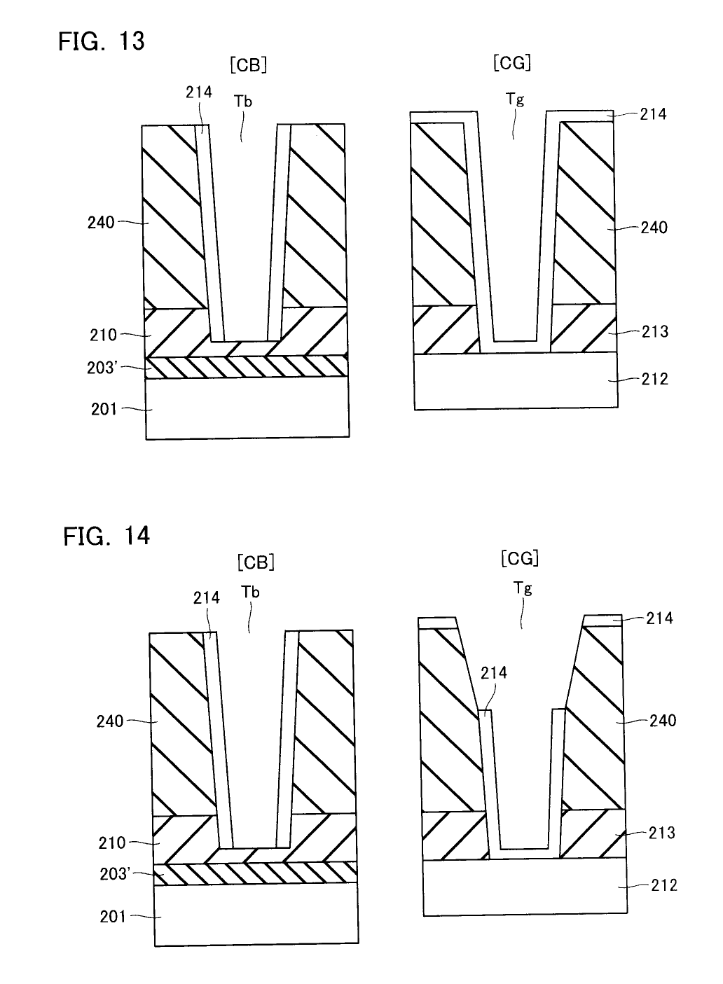

Then, as shown in FIG. 13, the photolithography and etching technologies are used to deposit a not-shown mask material in a region other than the trench Tb, and then the RIE is used to remove the portion of the amorphous silicon film 214 that is formed at the bottom of the trench Tb. Then, the above mask material is removed by ashing or the like. In so doing, the photolithography does not need a high accuracy and high cost exposure such as the ArF immersion exposure system. A low cost exposure is sufficient such as, for example, an i-line exposure system.

Then, as shown in FIG. 14, another mask material (not shown) is deposited in a region other than the upper end portion of the trench Tg, and then, using the mask material, the anisotropic etching is performed to widen the upper end portion of the trench Tg. This removes the amorphous silicon film 214 near the upper end of the trench Tg and also widens the upper end portion of the trench Tg.

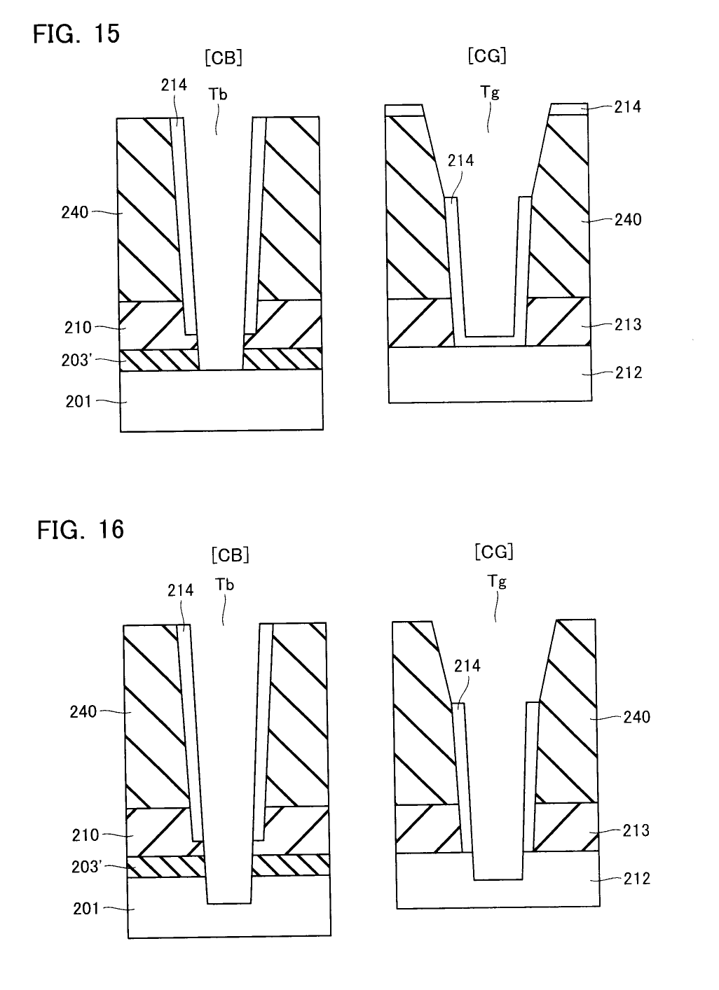

Then, as shown in FIG. 15, a predetermined etching condition (including the temperature, the pressure, the etching gas type, and the time) is set and a first reactive ion etching (RIE) is performed. In the first RIE, an etching condition (a first etching condition) is set in which the etching rate of the silicon oxide film and the silicon nitride film is sufficiently higher than the etching rate of the amorphous silicon film. Thus, in the trench Tb in which the contact CB is to be formed, because the bottom of the amorphous silicon film 214 is already removed, the stopper film 210 and the gate-insulating film 203′ positioned at the bottom of the trench Tb are removed. The first RIE has a low etching rate for the amorphous silicon. The first RIE may thus etch away the stopper film 210 and the gate-insulating film 203′ while protecting the side wall of the trench Tb. Meanwhile, in the trench Tg where the contact CG is to be formed, the amorphous silicon film 214 still remaining at its bottom retards the etching of the trench Tg. Therefore, even if the trenches Tb and Tg are processed at the same time, it may be possible to prevent overetch in the trench Tg from penetrating the conductive film 212.

Then, as shown in FIG. 16, an etching condition (a second etching condition) different from that of the first RIE in FIG. 15 is set and the second RIE is performed. In the second RIE, the difference between the etching rate of the amorphous silicon and the etching rate of the silicon oxide film and the silicon nitride film is set smaller than that in the first RIE. Therefore, in the second RIE, even in the trench Tg, the amorphous silicon positioned at the bottom continues to be etched, and the trench Tg passes through the amorphous silicon film 214 at the bottom to reach the conductive film 212. In so doing, because the trench Tb already passes through the stopper film 210 and the gate-insulating film 203, it is unlikely that the trench Tg experiences overetching.

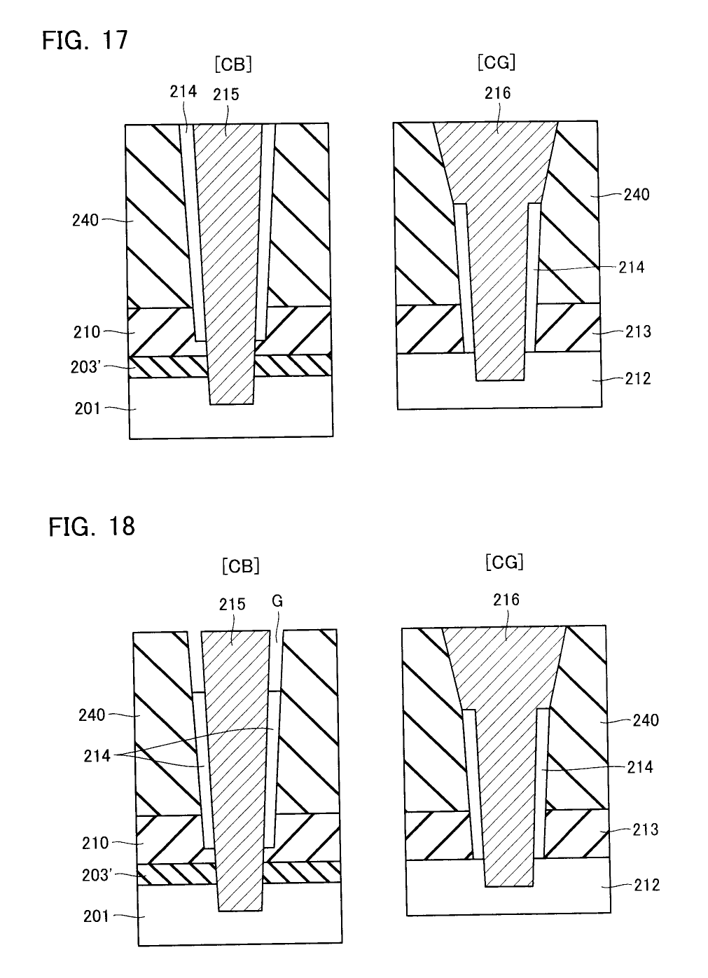

Next, as shown in FIG. 17, the trenches Tb and Tg are filled with the respective metal films 215 and 216 such as tungsten to form the respective contacts CB and CG.

Then, as shown in FIG. 18, the wet etching with, for example, a choline alkaline solution or the like is used to etch away the amorphous silicon film 214 near the upper end of the trench Tb to form the air gap G. Then, the interlayer dielectric film 241 including a material such as a dTEOS film is formed above the air gap G to complete the structures of the contacts CB and CG shown in FIG. 5.

As shown in FIG. 3, the contacts CB are arranged in the X-direction at a narrow pitch. Thus, as the wiring lines become finer, the breakdown voltage between the adjacent contacts becomes an issue. However, the contact CB in this embodiment includes the air gap G in the upper end portion that may improve the breakdown voltage between the contacts.

As described above, the non-volatile semiconductor memory device (the semiconductor device) in this embodiment includes the amorphous silicon layer 214 between the metal film 215 included in the contact CB and the interlayer dielectric film 240, specifically on the side walls of the trench Tb and the trench Tg. The amorphous silicon 214 may prevent the overetching of the conductive film 212 without increasing the number of steps, even when the trenches Tb and Tg are opened at the same time.

In addition, in the manufacturing method according to this embodiment, as shown in FIG. 13, the amorphous silicon layer 214 at the bottom of the trench Tb is removed, and then the first and second RIEs are performed in different etching conditions. Thus, the trenches Tb and Tg may be formed without the overetching.

### Second Embodiment

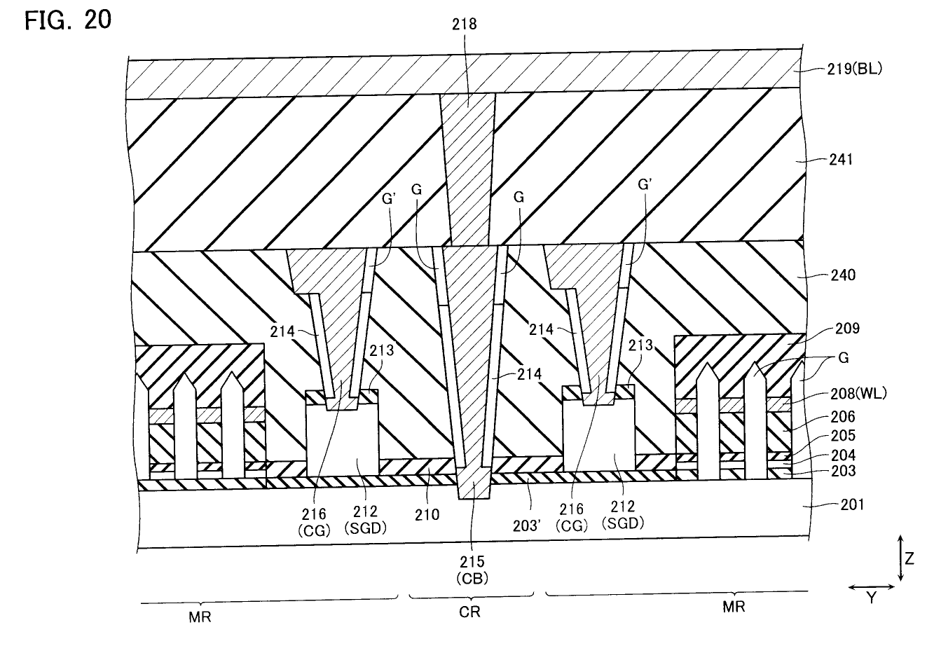

Next, with reference to FIG. 20, a non-volatile semiconductor memory device according to a second embodiment will be described. The non-volatile semiconductor memory device in the second embodiment has generally the same entire configuration as the device in the first embodiment (FIGS. 1 to 3). In addition, the configuration of the cross-sectional view along the A-A in FIG. 3 is the same as that shown in FIG. 4. Note, however, that the second embodiment has a different structure in the cross-sectional view along the B-B in FIG. 3, as follows.

FIG. 20 is the cross-sectional view along the B-B in FIG. 3 of the non-volatile semiconductor memory device according to the second embodiment. Like elements as those in the first embodiment (FIG. 5) are designated with like reference numerals in FIG. 20, and repeated description thereof is omitted below. The second embodiment includes an air gap G′ at the upper end of the contact CG unlike the first embodiment.

As shown in FIG. 20, in widening the opening portion at the upper end of the trench Tg, if the necessary mask material is formed in the correct position, the amorphous silicon layer 412 is etched away in the upper end portion of the trench Tg.

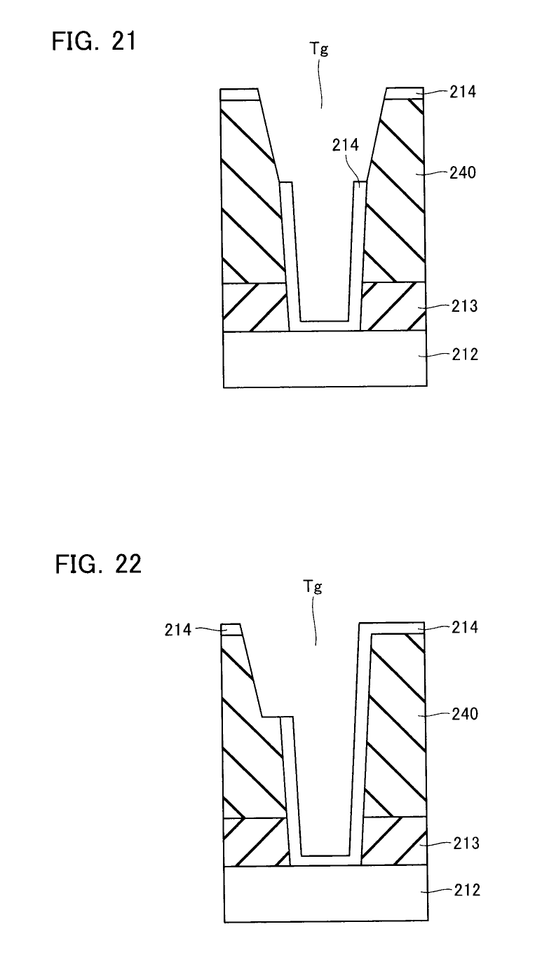

However, as shown in FIG. 21, in widening the opening portion at the upper end of the trench Tg, if the necessary mask material is formed in a misaligned position, the amorphous silicon layer 412 remains unetched at one end in the upper end portion of the trench Tg. By way of example, FIG. 22 shows a mask material shifted to the left side in FIG. 22. In this case, on the right side surface of the trench Tg, the amorphous silicon layer 214 may not be etched away and remain there.

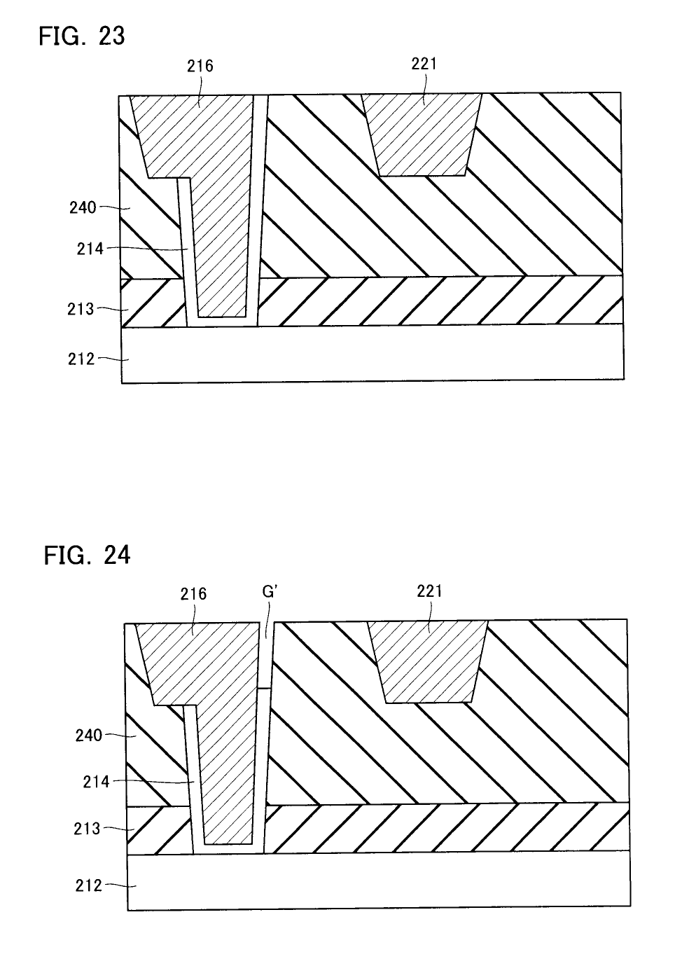

Note, however, that even in this case, after the metal film 216 is embedded as shown in FIG. 23, the amorphous silicon layer 214 remaining on the side wall of the trench Tb may be etched away as shown in FIG. 24. This etching process may be performed at the same time as the process in the first embodiment as shown in FIG. 18. Thus, the air gap G′ is formed on the side wall of the trench Tb. The amorphous silicon layer 214 remaining in the upper end portion of the trench Tb reduces the breakdown voltage with the adjacent wiring line layer 221. The air gap G′ thus formed may limit the reduction of the breakdown voltage.

### [Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate;
a conductive film mounted on the semiconductor substrate;
an interlayer dielectric film covering the conductive film and the semiconductor substrate;
a first contact extending from a surface of the interlayer dielectric film to the semiconductor substrate;
a second contact extending from a surface of the interlayer dielectric film to the conductive film; and
an amorphous silicon film disposed between the first or second contact and the interlayer dielectric film.

2. The semiconductor device according to claim 1, wherein
the first contact extends through a stopper film on the semiconductor substrate to the semiconductor substrate, the stopper film being formed of a silicon nitride film.

3. The semiconductor device according to claim 1, wherein
the second contact extends through a cap film on the conductive film to the conductive film, the cap film being formed of a silicon nitride film.

4. The semiconductor device according to claim 1, wherein
the first contact extends through a stopper film on the semiconductor substrate to the semiconductor substrate, the stopper film being formed of a silicon nitride film, and
the second contact extends through a cap film on the conductive film to the conductive film, the cap film being formed of a silicon nitride film.

5. The semiconductor device according to claim 1, further comprising an air gap between the first contact and the interlayer dielectric film in an upper portion of the amorphous silicon film.

6. The semiconductor device according to claim 5, wherein
the first contact extends through a stopper film on the semiconductor substrate to the semiconductor substrate, the stopper film being formed of a silicon nitride film.

7. The semiconductor device according to claim 5, wherein
the second contact extends through a cap film on the conductive film to the conductive film, the cap film being formed of a silicon nitride film.

8. The semiconductor device according to claim 6, wherein,
the first contact extends through a stopper film on the semiconductor substrate to the semiconductor substrate, the stopper film being formed of a silicon nitride film, and
the second contact extends through a cap film on the conductive film to the conductive film, the cap film being formed of a silicon nitride film.

9. The semiconductor device according to claim 1, wherein
the second contact comprises a first conductive layer formed in contact with the amorphous silicon film and a second conductive layer disposed above the first conductive layer, and
the amorphous silicon layer has an upper end below the second conductive layer.

10. The semiconductor device according to claim 9, further comprising a first air gap between the first contact and the interlayer dielectric film in an upper portion of the amorphous silicon film.

11. The semiconductor device according to claim 10, further comprising a second air gap between the second conductive layer and the interlayer dielectric film.

12. A method of manufacturing a semiconductor device comprising:
forming a conductive film on a semiconductor substrate;
forming a cap film on the conductive film;
forming a stopper film on the semiconductor substrate;
forming an interlayer dielectric film covering the conductive film and the semiconductor substrate;
forming a first trench through the interlayer dielectric film to the stopper film, and forming a second trench through the interlayer dielectric film to the conductive film;
forming an amorphous silicon film along inner walls of the first and second trenches;
selectively removing an amorphous silicon film formed at a bottom of the first trench;
performing a first etching according to a first etching condition to remove the stopper film formed at the bottom of the first trench;
performing a second etching according to a second etching condition different from the first etching condition to remove the amorphous silicon layer formed at the bottom of the second trench; and
embedding a metal film in the first and second trenches to form first and second contacts.

13. The method of manufacturing a semiconductor device according to claim 12, wherein
the first etching condition is such that the etching rate of a silicon oxide film and a silicon nitride film is sufficiently higher than an etching rate of an amorphous silicon film.

14. The method of manufacturing a semiconductor device according to claim 13, wherein
the second etching condition is such that the difference between the etching rate of a silicon oxide film and a silicon nitride film and the etching rate of an amorphous silicon film is smaller than the difference in the first etching condition.

15. The method of manufacturing a semiconductor device according to claim 11, wherein
an amorphous silicon layer in an upper end portion of the first or second trench is etched away to form an air gap between the first or second contact and the interlayer dielectric film.

16. The method of manufacturing a semiconductor device according to claim 14, wherein
an etching is performed to widen an upper end of the second trench to remove the amorphous silicon film near the upper end.
